(19) United States
(12) Patent Application Publication
(10) Pub. No.: US 2025/0093112 A1
(43) Pub. Date: Mar. 20, 2025

(54) DUAL MODE HEAT ENERGY COLLECTOR

(71) Applicant: Raytheon Systems Limited, Harlow (GB)

(72) Inventor: David L. Gordon, Kirkcaldy (GB)

(21) Appl. No.: 18/886,503

(22) Filed: Sep. 16, 2024

(30) Foreign Application Priority Data
Sep. 20, 2023 (GB) 2314411.6

(51) Int. Cl. F28F 3/06; F28F 13/00; F28F 23/02

(52) U.S. Cl. CPC F28F 3/06; F28F 23/02; F28F 2013/001; F28F 2215/04

(57) ABSTRACT

A dual mode heat energy collector includes a base having a first surface arranged to provide heat energy to a heat energy consuming object and a second surface; and heat energy absorbing fins attached to and extending from the second surface; wherein the base further includes at least one liquid channel arranged between the first surface and the second surface, the at least one liquid channel being defined by one or more walls forming a heat conducting connection between the second surface and the first surface.

### CROSS-REFERENCE TO RELATED APPLICATION AND PRIORITY CLAIM

This application claims priority under 35 U.S.C. § 119 to United Kingdom Patent Application No. 2314411.6 filed on Sep. 20, 2023, which is hereby incorporated by reference in its entirety.

### TECHNICAL FIELD

The present application relates to a dual mode heat energy collector, and in particular to a dual mode heat energy collector suitable for collecting heat from either a gas or a liquid.

### BACKGROUND

Heat pumps are commonly used to obtain heat energy from the ambient environment, so that the obtained heat energy can be used for a useful purpose, such as domestic heating and/or water heating. There are a number of known types of heat pumps using different mechanisms to collect heat energy from the environment, so that the heat energy can be transferred to a mechanism able to use it. For example, domestic heat pumps typically collect heat energy from air or water in the local environment and provide this heat energy to a domestic heating system to provide hot water and/or domestic space heating.

In practice there is a problem that a large number of different designs of heat pumps are required for different applications and for obtaining heat from different sources, requiring an inventory of a large number of different heat pumps and components to be maintained for manufacture, repair and maintenance, leading to undesirable expense, and making the logistics of repair and maintenance complex. Further, a large number of different heat pump designs and components must be tested and certified, increasing costs further.

The embodiments described below are not limited to implementations which solve any or all the disadvantages of the known approaches described above.

### SUMMARY

This Summary is provided to introduce a selection of concepts in a simplified form that are further described below in the Detailed Description. This Summary is not intended to identify key features or essential features of the claimed subject matter, nor is it intended to be used to determine the scope of the claimed subject matter; variants and alternative features which facilitate the working of the invention and/or serve to achieve a substantially similar technical effect should be considered as falling into the scope of the invention disclosed herein.

In a first aspect of the present invention, there is provided a dual energy collector comprising: a base comprising; a first surface arranged to provide heat energy to a heat energy consuming object, and a second surface; and heat energy absorbing fins attached to and extending from the second surface; wherein the base further comprises at least one liquid channel arranged between the first surface and the second surface, the at least one liquid channel being defined by one or more walls forming a heat conducting connection between the second surface and the first surface.

This may provide the advantages of improved flexibility of use of the dual mode heat energy collector, whereby the same dual mode heat energy collector may be used in both applications requiring gas-source heat energy collection and applications requiring liquid-source heat energy collection, and may be used to obtain heat energy from either or both a gas-source and a liquid source. This may reduce the number of different heat energy collector designs which must be produced, tested and certified, and maintained in inventory for use in manufacturing, repair, and maintenance tasks, thus reducing costs and simplifying logistics.

In a preferred example, the heat energy absorbing fins define gas flow channels between them. This may provide the advantage of more efficient heat energy absorption from the gas.

In a preferred example, the heat energy absorbing fins are located across an area of the second surface, and the liquid channels and walls are arranged within the base at locations corresponding to the area of the second surface. This may provide the advantage of improved heat conduction from the heat energy absorbing fins to the heat energy absorbing object.

In a preferred example, the heat energy absorbing fins comprise a plurality of parallel fins and the walls extend parallel to the fins. This may provide advantages of ease of manufacture and improved heat conduction from the heat energy absorbing fins to the heat energy consuming object.

In a preferred example, the heat energy absorbing fins have a pitch equal to, or an integer multiple of, a pitch of the walls, and each heat energy absorbing fin is aligned with a respective wall. This may provide advantages of improved heat conduction from the heat energy absorbing fins to the heat energy consuming object and increased structural strength.

In a preferred example, the dual mode heat energy collector is arranged to be operable in a first, gas source, mode in which heat energy is collected by the dual mode heat energy collector from gas flowing past the heat energy absorbing fins, or in a second, liquid source mode, in which heat energy is collected by the dual mode heat energy collector from liquid flowing through the at least one liquid channel; and the rate of heat transfer from the gas in the first, gas source, mode is substantially the same as the rate of heat transfer from the liquid in the second, liquid source, mode. This may provide the advantage that the same dual mode heat energy collector may be used in a particular application regardless of whether gas-source or liquid-source heat energy collection is to be used and may simplify changing the dual mode heat energy collector between a gas-source and a liquid source of heat energy. This may further reduce the number of different heat energy collector designs which must be produced, tested and certified, and maintained in inventory for use in manufacturing, repair, and maintenance tasks, thus reducing costs and simplifying logistics.

In a preferred example, the at least one liquid channel comprises a plurality of parallel liquid channels. This may provide the advantages of improved efficiency of liquid-source heat energy collection.

In a preferred example, the base and the heat energy absorbing fins are integrally formed. This may provide the advantage of improved heat conduction between the heat energy absorbing fins and the heat energy consuming object.

In a preferred example, the walls and the first and second surfaces of the base are integrally formed. This may provide the advantages of improved heat conduction between the heat energy absorbing fins and the heat energy consuming object and between the walls and the heat energy consuming object.

In a preferred example, the dual mode heat energy collector is produced by additive manufacturing. This may provide the advantages of efficient and cheap manufacturing.

In a preferred example, the body and heat energy absorbing fins comprise aluminum, copper, or alloys thereof. This may provide the advantages of improved heat conduction throughout the heat energy collector.

In a preferred example, the heat energy consuming object is a heat pump. This may provide advantages in efficient and cheap installation and support of heat pumps.

In a second aspect of the present invention, there is provided a heat energy collecting system comprising: a dual mode heat energy collector according to the first aspect; a heat energy consuming object in thermal contact with the first surface; and at least one of: a gas flow generator arranged to produce a gas flow past the heat energy absorbing fins; and a liquid flow generator arranged to produce a liquid flow through the at least one liquid channel. This may provide corresponding advantages to the first aspect.

In a preferred example, the system comprises either: a gas flow generator arranged to produce a gas flow past the heat energy absorbing fins; or a liquid flow generator arranged to produce a liquid flow through the at least one liquid channel. This may provide the advantage that the same dual mode heat energy collector may be used in a particular cooling application regardless of whether a gas-source or a liquid-source of heat energy is to be used. This may further reduce the number of different heat energy collector designs which must be produced, tested and certified, and maintained in inventory for use in manufacturing, repair, and maintenance tasks, thus reducing costs and simplifying logistics.

In a preferred example, the dual mode heat energy collector is arranged so that the rate of heat transfer from the gas flow is substantially the same as the rate of heat transfer from the liquid flow. This may provide the advantage that the same dual mode heat energy collector may be used in a particular heat energy collection application regardless of whether a gas-source or a liquid-source of heat energy is to be used. This may further reduce the number of different heat energy collector designs which must be produced, tested and certified, and maintained in inventory for use in manufacturing, repair, and maintenance tasks, thus reducing costs and simplifying logistics.

In a preferred example, the gas flow generator comprises a fan. This may provide the advantage of improved heat energy collection from the gas.

In a preferred example, the gas flow comprises air. This may provide the advantages that air is readily available at low cost.

In a preferred example, the liquid flow generator comprises a pump and a heat exchanger. This may provide the advantages of improved heat energy collection from the liquid, and allowing a closed liquid circuit to be used.

In a preferred example, the liquid flow comprises water. This may provide the advantages that water is readily available at low cost, and has a high heat capacity to provide and transport heat energy.

In a preferred example, the heat consuming object is a heat pump. This may provide advantages in efficient and cheap installation and support of heat pumps.

In a third aspect of the present invention, there is provided a method of providing heat energy to a heat energy consuming object, the method comprising: providing a dual mode heat energy collector according to the first aspect; arranging the first surface of the dual mode heat energy collector in contact with a heat energy consuming object; and providing at least one of: a gas flow past the heat energy absorbing fins; and a liquid flow through the at least one liquid channel. This may provide corresponding advantages to the first aspect.

In a preferred example, the method comprises either: providing a gas flow past the heat energy absorbing fins; or providing a liquid flow through the at least one liquid channel.

In a preferred example, the heat consuming object is a heat pump. This may provide advantages in efficient and cheap installation and support of heat pumps.

The features and embodiments discussed above may be combined as appropriate, as would be apparent to a person skilled in the art, and may be combined with any of the aspects of the invention except where it is expressly provided that such a combination is not possible or the person skilled in the art would understand that such a combination is self-evidently not possible.

### BRIEF DESCRIPTION OF THE DRAWINGS

Embodiments of the invention will be described, by way of example only and with reference to the following drawings, in which:

FIG. 1 shows a perspective view from above of a dual mode heat energy collector according to a first embodiment;

FIG. 2 shows a perspective view from below of the dual mode heat energy collector of FIG. 1;

FIG. 3 shows a partial cross-sectional view along the line A-A in FIG. 1;

FIG. 4 shows a side view of a dual mode heat energy collector according to a second embodiment;

FIG. 5 shows a cut-away view of the dual mode heat energy collector of FIG. 4;

FIG. 6 shows a schematic diagram of the dual mode heat energy collector of FIG. 4 operating in a gas source mode; and

FIG. 7 shows a schematic diagram of the dual mode heat energy collector of FIG. 4 operating in a liquid source mode.

### DETAILED DESCRIPTION

Embodiments of the present invention are described below by way of example only. These examples represent the best mode of putting the invention into practice that are currently known to the Applicant although they are not the only ways in which this could be achieved. The description sets forth the functions of the example and the sequence of step for constructing and operating the example. However, the same or equivalent functions and sequences may be accomplished by different examples.

In summary, the present disclosure provides a dual mode heat energy collector able to collect heat energy from both a liquid and a gas as a heat energy source in the same heat energy collector structure. The ability to use collect heat energy from both a liquid and a gas by the same heat energy collector structure provides improved flexibility of use of the dual mode heat energy collector.

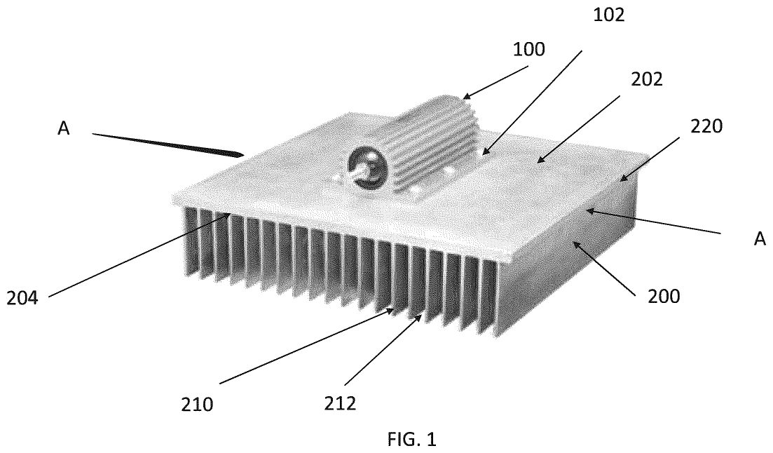

FIG. 1 shows a perspective view from above of a dual mode heat energy collector 200 according to a first embodiment. The heat energy collector 200 comprises a base in the form of a base plate 220 having a first surface 202 and a second surface 204 on opposite sides of the base plate 220. The first and second surfaces 202 and 204 are substantially planar and parallel. In the illustrated example of FIG. 1 the first surface 202 faces upward and the second surface 204 faces downward, but this is for convenience of illustration only. The dual mode heat energy collector 200 may be arranged in any orientation in operation, as necessary.

The first surface 202 of the dual mode heat energy collector 200 is suitable for a heat energy consuming object 100, to be attached to the heat energy collector 200 in heat conducting contact so that the heat energy collector 200 can provide heat energy to the heat energy consuming object 100 by heat energy which has been collected from the surrounding environment by the dual mode heat energy collector 200 travelling by conduction to the heat energy consuming object 100 in contact with the heat energy collector 200. As shown in FIG. 1, the heat energy collector 200 and the heat energy consuming object 100 in combination are comprised in a heat energy collecting system in which the heat energy consuming object 100 is provided with heat energy gathered from the environment. The heat consuming object 100 may alternatively be referred to as a heat energy absorbing, or heat energy using, object. The heat consuming object 100 may, for example, be an evaporator forming a cold element of a heat pump which takes heat energy from the environment and uses the heat energy to provide hot water and/or space heating. In some examples, the heat consuming object 100 may be a domestic heat pump.

In the illustrated example of FIG. 1, the heat energy consuming object 100 is attached to the first surface 202 of the heat energy collector 200. The heat energy consuming object 100 may be releasably attached to the heat energy collector 200. In the illustrated example of FIG. 1, the heat energy consuming object 100 is releasably attached to the heat energy collector 200 via a plurality of bolts 102. Alternatively, in other examples, the heat energy consuming object 100 can be permanently attached to the heat energy collector 200. For example, the heat energy consuming object 100 can be permanently attached to the heat energy collector 200 via welding or an adhesive layer. The described means of attachment are examples only, and other releasable or permanent attachment means can be used in alternative examples.

In the illustrated example of FIG. 1, the heat energy consuming object 100 is an evaporator forming a cold element of a heat pump. As is well known, evaporators capture and consume imported heat energy, using the heat energy to convert a liquid to a gas. Commonly, the liquid is water. However, this is by way of example only, and any number or type of heat energy consuming objects requiring heat energy may be used with the heat energy collector 200. For example, the heat energy consuming object 100 may be an evaporator having a food processing, agricultural, chemical separation, or waste management function, instead of an evaporator of a heat pump, Further, the heat consuming object 100 may not be an evaporator. These examples are not intended to be exhaustive.

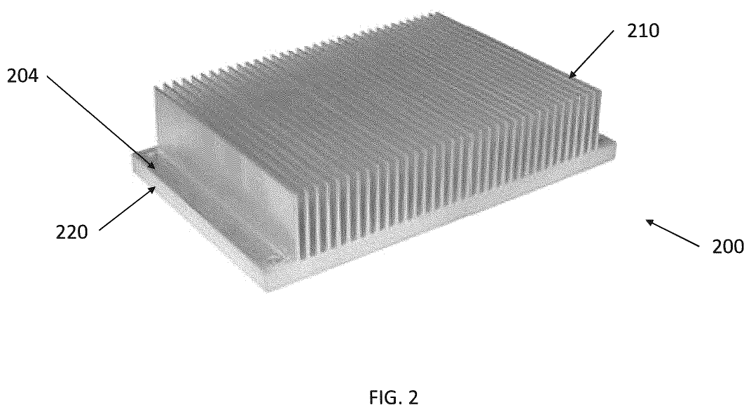

FIG. 2 shows a perspective view from below of the dual mode heat energy collector 200 according to the first embodiment. The heat energy consuming object 100 is not visible in FIG. 2.

As can be seen in FIGS. 1 and 2, the dual mode heat energy collector 200 comprises a plurality of heat energy absorbing fins 210 attached to the second surface 204 of the base plate 220. Accordingly, the base plate 220 may also be referred to a fin base. The heat energy absorbing fins 210 are each substantially flat and planar, are arranged parallel to one another, and extend perpendicularly to the second surface 204 of the base plate 220. The heat energy absorbing fins 210 define gas flow channels 212 between them. The heat energy absorbing fins 210 are located extending across an area of the second surface 204 of the base plate 220.

The illustrated example of FIGS. 1 and 2 has the heat energy absorbing fins 210 integrally formed with the base plate 220. Conveniently, these integrally formed heat energy absorbing fins 210 and base plate 220 can be formed by an additive manufacturing technique. In alternative examples, the heat energy absorbing fins 210 the base plate 220 can be formed from a single solid piece by machining. In other alternative examples, the heat energy absorbing fins 210 and the base 220 can be manufactured as separate parts and subsequently attached together. in such alternative examples, the heat energy absorbing fins 210 can be attached to the heat energy collector 200 via welding or a heat conductive adhesive layer.

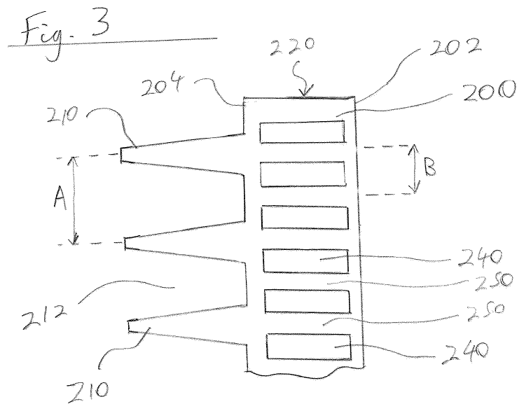

FIG. 3 shows a partial cross-sectional view of the dual mode heat energy collector 200 according to the first embodiment along the line A-A in FIG. 1.

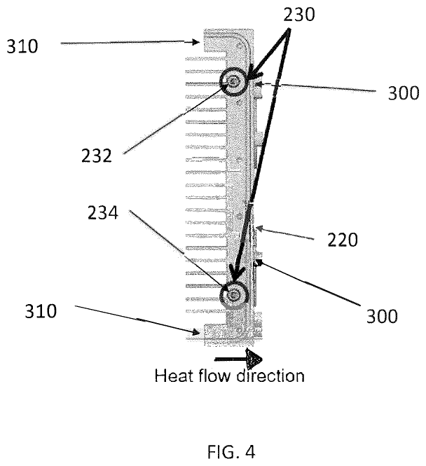

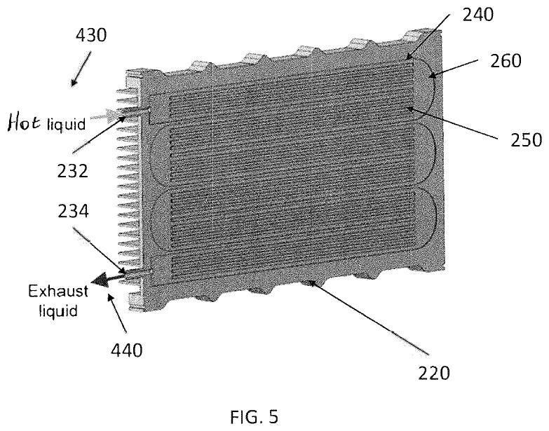

FIGS. 4 and 5 show views of a dual mode heat energy collector 200 according to a second embodiment. The heat energy consuming object 100 is not shown in FIGS. 4 and 5. The dual mode heat energy collector 200 of the second embodiment is the same as the dual mode heat energy collector 200 of the first embodiment, except that the dual mode heat energy collector 200 of the second embodiment 200 has mounting structures 300 on the first surface 202 for mounting one or more heat consuming objects, and also has connecting structures 310 on the second surface 204 for attaching the dual mode heat energy collector 200 to a supporting structure. The mounting structures 300 and connecting structures 310 are not essential, and may be omitted, as in the first embodiment, or take a different form, as required in any specific implementation.

FIG. 4 shows an end view of the dual mode heat energy collector 200 of the second embodiment. FIG. 5 shows a cut away view of the dual mode heat energy collector 200 of the second embodiment with the first surface 202 removed.

As shown in FIGS. 3 and 5, the base plate 220 contains a plurality of liquid flow channels 240 located between the first and second surfaces 202 and 204. The liquid flow channels 240 are defined between spaced apart walls 250 which extend between, and are integral with, the first and second surfaces 202 and 204. The walls 250 are each substantially flat and planar, are arranged parallel to one another, and extend perpendicularly to the first and second surfaces 202 and 204 of the base plate 220. As can be best seen in FIGS. 3 and 5, the walls 250 extend parallel to the heat energy absorbing fins 210.

As shown in FIG. 5, the liquid flow channels 240 are arranged to form groups of multiple parallel liquid flow channels 240, in the illustrated embodiment groups of five parallel liquid flow channels 240. The groups of liquid channels 240 are connected together at their ends by manifold sections 260 to form a serpentine, or zig-zag, shaped set of liquid flow channels 240 covering most of the area of the base plate 220. The liquid flow channels 240 and the walls 250 are arranged within the base plate 220 in locations corresponding to the area of the second surface 204 where the heat energy absorbing fins 210 are located, so that the walls 250 act as heat bridges thermally connecting the second surface 204 and the first surface 202, and can conduct heat energy from the heat energy absorbing fins 210 to the heat energy consuming object 100.

In the illustrated example of the first embodiment shown in FIG. 3, the heat energy absorbing fins 210 are evenly spaced with a first pitch A, where the first pitch A is the distance between the centerlines of adjacent parallel heat energy absorbing fins 210, and the walls 250 are also evenly spaced with a second pitch B, where the second pitch B is the distance between the centerlines of adjacent parallel walls 250. In the illustrated example, the first pitch A is double the second pitch B, and each heat energy absorbing fin 210 is arranged to be aligned with a respective one of the parallel walls 250. Since the first pitch is double the second pitch, alternate ones of the parallel walls 250 are aligned with respective ones of the heat energy absorbing fins 210.

In the illustrated example of FIG. 3, the heat energy absorbing fins 210 are 2 mm wide and the gas flow channels 212 are 6 mm wide, so that the first pitch is 8 mm. Further, in this example, the walls 250 are 2 mm thick, and the liquid flow channels 240 are 2 mm wide, so that the second pitch is 4 mm. The height of the walls 250 and the liquid flow channels 240 is 3 mm.

It is not essential that the first pitch of the heat energy absorbing fins 210 is equal to, or an integer multiple of, the second pitch of the walls 250, or that the heat energy absorbing fins 210 are aligned with respective ones of the walls 250. However, such an arrangement may provide an advantage of better conduction of heat energy from the heat energy absorbing fins 210 and through the walls 250 to the heat energy consuming object 100, and may provide a physically stronger structure.

In the illustrated example of the second embodiment shown in FIG. 5, the heat energy absorbing fins 210 are evenly spaced with a first pitch A, and the walls 250 are also evenly spaced with a second pitch B, and the first pitch A is greater than the second pitch B. However, in this example the first pitch is not an integer multiple of the second pitch. Accordingly, in the illustrated example of FIG. 5, the heat energy absorbing fins 210 are not all aligned with parallel walls 250, although some of the heat energy absorbing fins 210 may be aligned with a parallel wall 250. In the illustrated arrangement of FIG. 5 the first and second pitches are selected independently of one another. The first pitch of the heat energy absorbing fins 210 is selected to maximize the efficiency of heat energy collection from gas, and the second pitch of the walls 250 is selected to maximize the efficiency of heat energy collection from liquid. In some examples such independent selection of the first and second pitches may provide an advantage of better heat energy collection which outweighs any reduction in conduction of heat energy from the heat energy absorbing fins 210 through the walls 250 to the heat energy consuming object 100 resulting from the walls 250 and the heat energy absorbing fins 210 not being aligned.

In the illustrated example of FIG. 5, the heat energy absorbing fins 210 are 2 mm wide and the gas flow channels 212 are 4 mm wide, so that the first pitch is 6 mm. Further, in this example, the walls 250 are 2 mm thick, and the liquid flow channels 240 are 2 mm wide, so that the second pitch is 4 mm. The height of the walls 250 and the liquid flow channels 240 is 3 mm.

It may be preferred that the height of the walls 250 and the liquid flow channels 240 is in the range 1 mm to 3 mm. Without wishing to be bound by theory, this may provide a good balance between the ease of manufacture of the base plate 220 comprising the liquid flow channels 240 and the height of the walls 250 and liquid flow channels 240 being low enough for the walls 250 to provide a good path for heat flow through the base plate 220.

Without wishing to be bound by theory, it is expected that it will generally be preferred for the first pitch of the heat energy absorbing fins 210 to be greater than the second pitch of the walls 250, so that the gas flow channels 212 are wider than the liquid flow channels 240.

The dimensions given above are by way of example only, and different dimensions may be used. Without wishing to be bound by theory, it is expected that if the thickness of the walls 250 is too large, compared to the width of the liquid flow channels 240, the heat energy collection from liquid may be inefficient, but that if the thickness of the walls 250 is too small, compared to the width of the liquid flow channels 240, the conduction of heat from the heat energy absorbing fins 210 may be poor, making the heat energy collection from gas inefficient. Accordingly, in any specific implementation an optimum ratio between the thickness of the walls 250 and the width of the liquid flow channels 240 may be determined.

It is not essential that the walls 250 extend parallel to the heat energy collection fins 210. However, this may be advantageous to conduct the heat energy collected across the full length of the heat energy collection fins 210 to the heat energy consuming object 100, to improve heat energy collection efficiency in the first, gas-source, mode.

As shown in FIGS. 4 and 5, the heat energy collector 200 further comprises liquid openings 232 and 234 in a side surface of the base plate 220. The liquid openings 232 and 234 comprise a liquid inlet 232 and a liquid outlet 234. The liquid openings 232 and 234 are connected to the liquid flow channels 240. The liquid inlet 232 and liquid outlet 234 are arranged to allow liquid to flow through the liquid inlet 232 into the base 220 of the dual mode heat energy collector 200, through the serpentine shaped set of liquid flow channels 240, and through the liquid outlet 234 out of the base plate 220 of the dual mode heat energy collector 200. The arrangement of the liquid flow channels 240 into groups of parallel liquid flow channels 240 is not essential. However, this may reduce the flow resistance of a liquid flowing through the liquid flow channels, and so reduce the pressure drop of a flowing liquid between the liquid inlet 232 and the liquid outlet 234. Conveniently, the parts of the base plate 220 other than the liquid flow channels 240, manifold sections 260, and liquid inlet and outlet 232 and 234 may be solid between the first and second surfaces 202 and 204.

The illustrated examples have the walls 250 integrally formed with the base plate 220. Conveniently, these integrally formed walls 250 and base plate 220 can be formed by an additive manufacturing technique. In alternative examples, the liquid flow channels 240 can be formed by boring liquid flow channels 240 in a solid base plate 220, leaving the material of the walls 250 in place. In other alternative examples, the walls 250 and the base plate 220 can be manufactured as separate parts and subsequently attached together. In such alternative examples, the walls 250 can be attached to the first and second surfaces 202 and 204 of the base plate 220 of the heat energy collector 200 via welding or a heat conductive adhesive layer.

The heat energy absorbing fins 210 and the gas flow channels 212 defined between each of the heat energy absorbing fins 210 form a gas-source heat energy collection mechanism of the dual mode heat energy collector 200. The base plate 220 is arranged to transfer heat energy from the heat energy absorbing fins 210 to the heat energy consuming object 100 by conduction through the second surface 204 and the first surface 202 and the connecting parts of the base plate 220. In the region of the set of liquid channels 240 the heat energy can pass from the second surface 204 of the base plate 220 to the first surface 202 by conduction through the walls 250. The walls 250 form respective heat conducting connections between the second surface 204 and the first surface 202. Accordingly, the dimensions of the walls 250 must be selected to allow sufficient heat conduction between the second surface 204 and the first surface 202 to enable proper operation of the dual mode heat energy collector 200 in the first, gas source, mode. In particular, the spacing, thickness and height of the walls 250 must be appropriately selected. Without wishing to be bound by theory, it is expected that in practice it will be simplest to vary the thickness of the walls 250 to control the amount of heat conduction.

The liquid flow channels 240 defined between the walls 250 and the first and second surfaces 202 and 204 of the base plate 220 form a liquid-source heat energy collection mechanism of the dual mode heat energy collector 200. The base plate 220 is arranged to transfer heat energy from the walls 250 to the heat energy consuming object 100 by conduction through the first surface 202.

It might be expected that the presence of the liquid channels 240 and other elements of the liquid cooling mechanism within the base plate 220 would interfere with heat transfer through the base plate 220 between the heat energy absorbing fins 210 of the gas-source heat energy collection mechanism and the heat energy consuming object 100. However, in practice it has been found that the area of the base plate 220 required by the liquid channels 240 and the area of the base plate 220 required by the walls are both relatively small, so that locating the liquid-source heat energy collection mechanism within the base plate 220 does not interfere with operation of the gas-source energy collection mechanism.

The dual mode heat energy collector 200 is able to operate in a first, gas-source mode using the gas-source mechanism, or in a second, liquid-source, mode using the liquid source mechanism. Accordingly, the same dual mode heat energy collector 200 may be used in both applications requiring heat energy to be collected from a gas source and applications requiring heat energy to be collected from a liquid source. This may reduce the number of different heat energy absorber designs which must be maintained in inventory for use in manufacturing, repair, and maintenance tasks, reducing costs and simplifying logistics. Further, the dual mode heat energy collector 200 may be used in applications where the dual mode heat energy collector 200 can switch between collecting heat energy from a gas source and collecting heat energy from a liquid source. This may provide the benefit that the source providing the most heat energy can be always be utilized, even when the different sources provide different amounts of energy at different times. For example, a heat pump may be arranged to obtain heat energy from ambient air or a ground water source, where typically the ambient air will have a higher temperature during the day while the ground water has a higher temperature at night (when the ambient air cools but the water temperature remains substantially constant), and the dual mode energy collector 200 may allow a heat pump to use the higher temperature heat energy source at all times, increasing the efficiency of the heat pump. Further, in implementations where the dual mode heat energy absorber is provided integrally with a heat energy consuming object which is to be provided with heat energy by the heat energy absorber, this may allow the same integrated heat energy consuming object and heat energy absorber assembly be used in both gas-source applications and liquid-source applications. This may reduce the number of different integrated assemblies which must be maintained in inventory for use in manufacturing, repair, and maintenance tasks, reducing costs and simplifying logistics. Further, by allowing the same dual mode heat energy absorber or integrated assembly to be used in both applications requiring gas-source heat energy collection and applications requiring liquid-source heat energy collection the number of heat energy absorber and integrated assembly designs which must be tested and certified may be reduced, which may reduce costs.

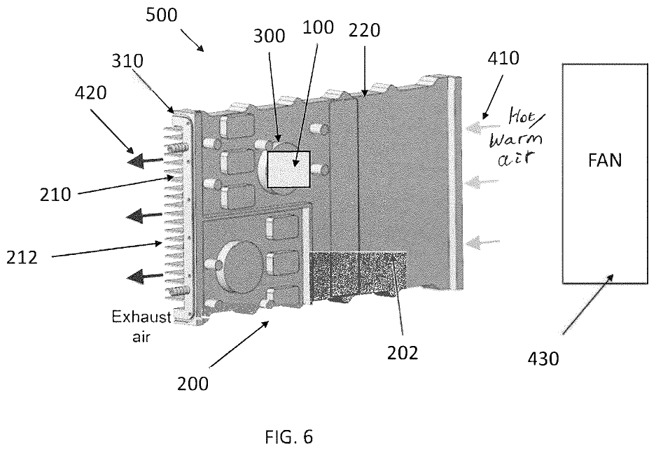

FIG. 6 shows a schematic diagram of the dual mode heat energy collector 200 comprised in a gas-source heat energy collection system 500, and arranged to operate in the first, gas-source, mode. The gas-source heat energy collection system 500 comprises the dual mode heat energy collector 200, a heat energy consuming object 100 in thermally conductive contact with the first surface 202 of the dual mode heat energy collector 200, and a gas flow generator fan 430.

When the dual mode heat energy collector 200 operates in the first, gas-source mode as part of the gas-source heat energy collection system 500, the dual mode heat energy collector 200 collects heat energy from gas flows driven by the fan 430 through the gas flow channels 212 defined between each of the heat energy absorbing fins 210 and provides this collected heat energy to the heat energy consuming object 100, so providing the heat energy consuming object 100 with the heat energy it requires. The gas flows into the gas flow channels 212 as a warm or hot gas 410, flows past the heat energy absorbing fins 210 and the second surface 204, which heat energy absorbing fins 210 and the second surface 204 collect or absorb heat energy from the gas, and is exhausted from the gas flow channels 212 as a cool exhaust gas 420. Accordingly, heat energy is collected from the gas by the dual mode heat energy collector 200. Whilst the gas is passing through the gas channels 212 between the heat energy absorbing fins 210, heat energy from the gas is collected by the heat energy absorbing fins 210 and the second surface 204, and the collected heat energy is conducted through the walls 250, acting as heat bridges, to the first surface 202 and through the first surface 202 to the heat energy consuming object 100. Accordingly, the gas-source heat energy collection system 500 is able to provide the heat energy consuming object 100 with heat energy collected from the to the gas 410. In some examples, the heat energy consuming object 100 is a cold element of a heat pump and the gas 410 may be ambient air or hot or warm air or gas produced as an exhaust from an industrial process.

In the illustrated example of FIG. 6, the gas flows into and out of the gas flow channels 212 as a pumped flow driven by the fan 430 located upstream of the gas flow channels 212. In alternative examples, one or more fans 430 may alternatively, or additionally, be located downstream of the gas flow channels 212. In alternative arrangements, the fan 430 may be replaced by an alternative driver for a gas flow. For example, the fan 430 may be replaced by an external gas pump, or a pressurized gas reservoir arranged to release a gas flow. These examples are not intended to be exhaustive. In the illustrated example of FIG. 6 the cooling gas is air, but this is not essential, and other gasses may be used in alternative examples.

In other examples, instead of a driven gas flow driven by the fan 430, the gas-source heat energy collection system 500 may be arranged to generate convection gas flows through the gas flow channels 212 driven by thermal expansion of the gas, or gas flows driven by ambient gas movement, without any external mechanism driving the gas flow. In examples where the cooling gas is air, ambient gas movement may be provided by the wind, or by movement of a vehicle comprising the gas-source heat energy collection system 500 relative to the air.

In some examples, in addition to flowing through the gas flow channels 212, gas may also flow past and absorb heat energy from the heat energy absorbing fins 210 located at the edges of the base plate 220.

When the dual mode heat energy collector 200 is to be used in a gas-source heat energy collection system 500 the liquid flow channels 240 may be filled with a gas, filled with a liquid, or contain a vacuum, as desired in any specific implementation. In examples where the liquid flow channels 240 are filled with a gas and/or a liquid the liquid openings 232 and 234 may be sealed to retain the gas and/or liquid, and means (not shown) may be provided to allow for thermal expansion of the gas and/or liquid to prevent excessive pressure build up within the liquid flow channels due to thermal expansion when the heat energy collector 200 increases in temperature, for example due to an increase in the temperature of the gas. It may be preferred for the liquid flow channels 240 to contain a liquid to keep the mass of the dual mode heat energy collector 200 the same in both operating modes. Further, it may be preferred for the liquid flow channels 240 to contain a liquid to improve the physical strength of the base plate 220. As is explained above, heat energy can pass from the second surface 204 of the base plate 220 to the first surface 202 by conduction through the walls 250, and, without wishing to be bound by theory, it is expected that the dual mode heat energy collector 200 will be designed to have sufficient thermal conductivity between the second and first surfaces 204 and 202 of the base plate 220 through the walls 250 and other solid parts of the base plate 220 without having to take into account heat energy passing through the liquid flow channels 240. However, in some examples it may be preferred to have gas and/or liquid within the liquid flow channels 240 to provide increased thermal conductivity. In some examples it may be preferred to leave the liquid openings 232 and 234 unsealed so that the liquid flow channels 240 are filled with air or vacuum, depending upon the ambient environment in which the dual mode heat energy collector 200 is located.

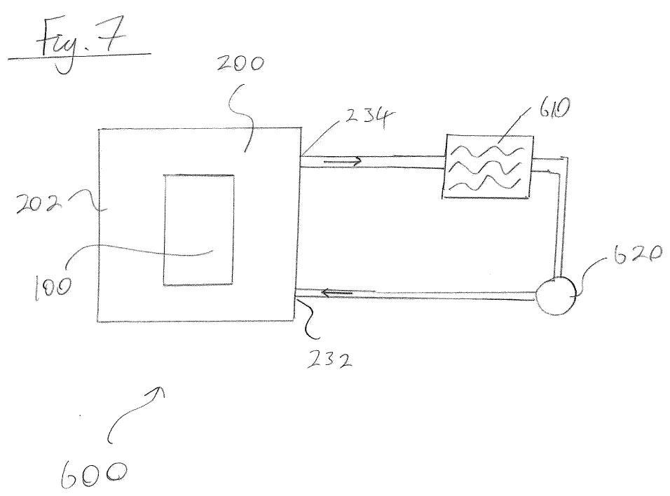

FIG. 7 shows a schematic diagram of the dual mode heat energy collector 200 comprised in a liquid-source heat energy collection system 600, and arranged to operate in the second, liquid-source mode. The liquid-source heat energy collection system 600 comprises the dual mode heat energy collector 200, a heat energy consuming object 100 in thermally conductive contact with the first surface 202 of the dual mode heat energy collector 200, and a liquid flow generator formed by a heat exchanger 610 in fluid flow connection between the liquid inlet 232 and the liquid outlet 234, and a liquid pump 620 arranged to pump liquid around a liquid flow circuit formed by the dual mode heat energy collector 200 and the heat exchanger 610. In the illustrated example the liquid is water. Other liquids may be used in alternative examples.

When the dual mode heat energy collector 200 operates in the second, liquid-source, mode as part of the liquid-source heat energy collection system 600, the dual mode heat energy collector 200 collects heat energy from hot or warm liquid moving through the liquid flow channels 240 from the liquid inlet 232 to the liquid outlet 324. As the liquid passes through the liquid flow channels 240, heat energy from the hot or warm liquid is collected by the first surface 202 of the base plate 220 and the walls 250, and the dual mode heat energy collector 200 provides this collected heat energy to the heat energy consuming object 100, so providing the heat energy consuming object 100 with the heat energy it requires. This also cools the liquid. The movement of the liquid transports the exhausted cooled liquid out of the heat energy collector 200 via the liquid outlet 324 to the heat exchanger 610 where the cooled liquid is heated by transferring heat energy from the external environment, such as a body of water or the atmosphere. The hot or warm liquid is then returned to the liquid inlet 232 of the dual mode heat energy collector 200. The flow of the liquid around the fluid circuit between the dual mode heat energy collector 200 and the heat exchanger 610 and through the liquid flow channels 240 is driven by the pump 620. Accordingly, heat energy is collected from the liquid by the dual mode heat energy collector 200. Whilst the liquid is passing through the liquid flow channels 240, heat energy from the liquid is collected by the walls 250 and the first surface 202, and the collected heat energy is conducted through the walls 250 and the first surface 202 to the heat energy consuming object 100. Accordingly, the liquid-source heat energy collection system 600 is able to provide the heat energy consuming object 100 with heat energy collected from the to the liquid. In some examples, the heat energy consuming object 100 is a cold element of a heat pump and the liquid may be heated by the heat exchanger 610 using ambient air or water, or hot or warm air, gas or water produced as an exhaust from an industrial process.

In other examples, instead of a closed circuit flow of the liquid, an open circuit arrangement can be used in which the liquid flows through the dual mode heat energy collector 200, and is then discarded. In examples using such open circuit arrangements, the liquid flow may be driven by pressure or gravity instead of being driven by a pump. In some examples the liquid may be ambient water, or hot or warm water produced as an exhaust from an industrial process. Without wishing to be bound by theory, arrangements with a closed circuit flow of liquid through the dual mode heat energy collector 200 may be advantageous in order to reduce the risk of damage or blockage of the liquid flow channels 240 by contaminants or biological organisms.

The dual mode heat energy collector 200 has dimensions and geometry selected so that the rate of transfer of heat energy from the gas or liquid to the dual mode heat energy collector 200 (that is, the rate of collection and transfer of heat energy to the attached heat consuming object) is the same, or substantially the same, in the first, gas-source, mode and in the second, liquid-source, mode. This may provide advantages in allowing the dual mode heat energy collector to be used in the same way, for example to provide heat energy to the same heat energy consuming object(s) regardless of whether gas-source or liquid-source operation is required.

As an alternative to the examples of use of the dual mode heat energy collector 200 described above, where the dual mode heat energy collector 200 operates in either a first gas-source mode, or a second liquid-source mode, the dual mode heat energy collector could be arranged to operate using both gas-source and liquid-source heat energy collection simultaneously. Such simultaneous use of gas-source and liquid-source heat energy collection could be continuous, or could be selective based on heat energy requirements. In some examples, the dual mode heat energy collector 200 could be switched between using different ones, or both, of gas-source and liquid-source heat energy collection based on changing circumstances and/or heat energy requirements.

In the illustrated examples the heat energy absorbing fins 210 are a plurality of flat, parallel strips extending perpendicular to the second surface 204 of the base plate 220. However, this is by way of example only, and the heat energy absorbing fins 210 are not limited to this geometry. The heat energy absorbing fins 210 may be curved or serpentine to define curved or serpentine gas flow channels between them. Other shapes and forms of heat energy absorbing fins may be used instead of, or in combination with, strips, such as pins and blocks, so long as the heat energy of the gas flowing past the heat energy absorbing fins 210 can be collected and conducted to the base plate 220. The surface area, materials, and surface texture of the heat energy absorbing fins 210 can be adjusted to control a rate of heat energy collection and transfer to the heat energy consuming object 100.

In the illustrated examples the walls 250 are a plurality of flat, parallel strips extending perpendicular to the first and second surfaces 202 and 204 of the base plate 220. However, this is by way of example only, and the walls 250 are not limited to this geometry. The walls 250 may be curved or serpentine to define curved or serpentine liquid flow channels 240 between them. The surface area, materials, and surface texture of the walls 250 can be adjusted to control a rate of heat energy collection and transfer to the heat energy consuming object 100.

In the illustrated examples the liquid openings 230 are positioned on the same side surface of the base plate 220. However, this is not essential. The liquid openings 230 are not limited to being positioned on a side surface of the base plate 220, or to being on a same surface of the base plate 220. The liquid openings 230 can be positioned any surface of the heat energy collector 200, provide that they are fluidly connected together by liquid flow channels having suitable geometry.

The heat energy collector 200 is made from a thermally conductive material or materials. The thermally conductive material may comprise aluminum, copper, alloys thereof, plastics materials, or any other material suitable for the conductive transfer of heat energy.

As is discussed above, the dual mode heat energy collector 200 can be manufactured using additive manufacturing techniques. This may advantageously allow the entire dual mode heat energy collector 200 including the heat energy absorbing fins 210 and walls 250 to be integrally formed.

In the illustrated examples the walls 250 extend substantially parallel to the heat energy absorbing fins 210. This may be advantageous to allow heat energy collected across the full length of the heat energy absorbing fins 210 to be passed by conduction through the walls 250 to the heat energy consuming object 100. However, it is not essential that the walls 250 are parallel to the heat energy absorbing fins 210. In other examples, the walls 250 and the heat energy absorbing fins 210 can extend in different directions. For example, the liquid tube 240 and heat energy absorbing fins 210 can extend perpendicularly. In other examples, the heat energy absorbing fins may have other shapes, such as pin fins, so that the heat energy absorbing fins 210 do not have an overall direction.

In the illustrated examples the flow channels comprise groups of five parallel flow channels. This is not essential, and alternative examples may use a different number of parallel flow channels.

In the illustrated examples base plate comprises liquid flow channels 240 defined by the walls 250. In other examples, these flow channels may be fluid flow channels for a fluid, such as a gas.

It will be understood that the benefits and advantages described above may relate to one embodiment or may relate to several embodiments. The embodiments are not limited to those that solve any or all of the stated problems or those that have any or all of the stated benefits and advantages. Variants should be considered to be included into the scope of the invention.

Any reference to “an” item refers to one or more of those items. The term “comprising” is used herein to mean including the method steps or elements identified, but that such steps or elements do not comprise an exclusive list and a method or apparatus may contain additional steps or elements.

Further, as used herein, the term “exemplary” is intended to mean “serving as an illustration or example of something”.

Further, to the extent that the term “includes” is used in either the detailed description or the claims, such term is intended to be inclusive in a manner similar to the term “comprising” as “comprising” is interpreted when employed as a transitional word in a claim.

The figures illustrate exemplary methods. While the methods are shown and described as being a series of acts that are performed in a particular sequence, it is to be understood and appreciated that the methods are not limited by the order of the sequence. For example, some acts can occur in a different order than what is described herein. In addition, an act can occur concurrently with another act. Further, in some instances, not all acts may be required to implement a method described herein.

The order of the steps of the methods described herein is exemplary, but the steps may be carried out in any suitable order, or simultaneously where appropriate. Additionally, steps may be added or substituted in, or individual steps may be deleted from any of the methods without departing from the scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. What has been described above includes examples of one or more embodiments. It is, of course, not possible to describe every conceivable modification and alteration of the above devices or methods for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims.

What is claimed is:

1. A dual mode heat energy collector comprising:
a base comprising a first surface arranged to provide heat energy to a heat energy consuming object and a second surface; and
heat energy absorbing fins attached to and extending from the second surface;
wherein the base further comprises at least one liquid channel arranged between the first surface and the second surface, the at least one liquid channel defined by one or more walls forming a heat conducting connection between the second surface and the first surface.

2. The dual mode heat energy collector of claim 1, wherein the heat energy absorbing fins define gas flow channels between them.

3. The dual mode heat energy collector of claim 1, wherein:
the heat energy absorbing fins are located across an area of the second surface; and
the liquid channels and walls are arranged within the base at locations corresponding to the area of the second surface.

4. The dual mode heat energy collector of claim 1, wherein:
the heat energy absorbing fins comprise a plurality of parallel fins; and
the walls extend parallel to the fins.

5. The dual mode heat energy collector of claim 4, wherein:
the heat energy absorbing fins have a pitch equal to, or an integer multiple of, a pitch of the walls; and
each heat energy absorbing fin is aligned with a respective wall.

6. The dual mode heat energy collector of claim 1, wherein:
the dual mode heat energy collector is arranged to be operable in a first mode in which heat energy is collected by the dual mode heat energy collector from gas flowing past the heat energy absorbing fins or in a second mode in which heat energy is collected by the dual mode heat energy collector from liquid flowing through the at least one liquid channel; and
a rate of heat transfer from the gas in the first mode is substantially the same as a rate of heat transfer from the liquid in the second mode.

7. The dual mode heat energy collector of claim 1, wherein the at least one liquid channel comprises a plurality of parallel liquid channels.

8. The dual mode heat energy collector of claim 1, wherein the base and the heat energy absorbing fins are integrally formed.

9. The dual mode heat energy collector of claim 1, wherein the walls and the first and second surfaces of the base are integrally formed.

10. The dual mode heat energy collector of claim 1, wherein the dual mode heat energy collector is produced by additive manufacturing.

11. The dual mode heat energy collector of claim 1, wherein the base and heat energy absorbing fins comprise aluminum, copper, or alloys thereof.

12. A heat energy collecting system comprising:
a dual mode heat energy collector comprising:
a base comprising a first surface and a second surface; and
heat energy absorbing fins attached to and extending from the second surface;
wherein the base further comprises at least one liquid channel arranged between the first surface and the second surface, the at least one liquid channel defined by one or more walls forming a heat conducting connection between the second surface and the first surface;
a heat energy consuming object in thermal contact with the first surface; and
at least one of:
a gas flow generator arranged to produce a gas flow past the heat energy absorbing fins; and
a liquid flow generator arranged to produce a liquid flow through the at least one liquid channel.

13. The heat energy collecting system of claim 12, wherein the system comprises either:
the gas flow generator arranged to produce the gas flow past the heat energy absorbing fins; or
the liquid flow generator arranged to produce the liquid flow through the at least one liquid channel.

14. The heat energy collecting system of claim 12, wherein the dual mode heat energy collector is arranged so that a rate of heat transfer from the gas flow is substantially the same as a rate of heat transfer from the liquid flow.

15. The heat energy collecting system of claim 12, wherein the gas flow generator comprises a fan.

16. The heat energy collecting system of claim 12, wherein the gas flow comprises air.

17. The heat energy collecting system of claim 12, wherein the liquid flow generator comprises a pump and a heat exchanger.

18. The heat energy collecting system of claim 12, wherein the liquid flow comprises water.

19. The heat energy collecting system of claim 12, wherein the heat energy consuming object is an evaporator.

20. A method of providing heat energy to a heat energy consuming object, the method comprising:
providing a dual mode heat energy collector comprising:
a base comprising a first surface and a second surface; and
heat energy absorbing fins attached to and extending from the second surface;
wherein the base further comprises at least one liquid channel arranged between the first surface and the second surface, the at least one liquid channel defined by one or more walls forming a heat conducting connection between the second surface and the first surface;
arranging the first surface of the dual mode heat energy collector in contact with a heat energy consuming object; and
providing at least one of:
a gas flow past the heat energy absorbing fins; and
a liquid flow through the at least one liquid channel.

21. The method of claim 20, wherein the method comprises either:
providing the gas flow past the heat energy absorbing fins; or
providing the liquid flow through the at least one liquid channel.
